(19) United States
(12) Patent Application Publication
(10) Pub. No.: US 2011/0240344 A1
(43) Pub. Date: Oct. 6, 2011

(54) DEPOSITION OF NANOWIRES AND OTHER NANOSCALE OBJECTS ON SURFACES

(75) Inventors: Michael S. Strano, Lexington, MA (US); Richa Sharma, Berkeley, CA (US)

(73) Assignee: Massachusetts Institute of Technology, Cambridge, MA (US)

(21) Appl. No.: 13/122,610

(22) PCT Filed: Oct. 20, 2009
(86) PCT No.: PCT/US09/05695

§ 371 Date: Jun. 15, 2011

Related U.S. Application Data
(60) Provisional application No. 61/107,302, filed on Oct. 21, 2008.

(51) Int. Cl. H05K 1/00; H01L 29/06; B32B 3/10; B32B 3/02; B82Y 99/00

(52) U.S. Cl. 174/250; 257/618; 428/195.1; 428/157; 428/209; 257/E29.024; 977/762

(57) ABSTRACT

The present invention generally relates to the deposition of nanowires and other nanoparticles on surfaces. According to one aspect of the invention, a fluid containing nanoscale objects, such as nanowires, is deposited on a surface having one or more relatively hydrophilic regions and one or more relatively hydrophobic regions. If the fluid is hydrophilic, it will preferentially be located in the relatively hydrophilic regions (or vice versa if the fluid is relatively hydrophobic). The fluid is then allowed to evaporate to cause the nanoscale objects to deposit. For instance, the rate of evaporation may be controlled so as to allow the nanoscale objects to substantially deposit at the centers of the regions and/or at a rate that causes the nanoscale objects to become substantially aligned. In some cases, the regions may be relatively small, e.g., having a minimum surface dimension of less than about 3000 nm. In one set of embodiments, one or more cylindrical droplets may be formed on the surface. For example, the surface may contain a relatively hydrophilic region, having a large surface aspect ratio, surrounded by a relatively hydrophobic region, such that an aqueous fluid deposited on the relatively hydrophilic region forms a cylindrical droplet. Other aspects of the present invention are directed to methods for creating and using such articles, methods for promoting such articles, or the like.

### RELATED APPLICATIONS

This application claims the benefit of U.S. Provisional Patent Application Ser. No. 61/107,302, filed Oct. 21, 2008, entitled “Deposition of Nanowires and Other Nanoscale Objects on Surfaces,” by Strand, et al., incorporated herein by reference.

### GOVERNMENT FUNDING

Research leading to various aspects of the present invention were sponsored, at least in part, by the National Science Foundation, Grant No. CBET-0758352. The U.S. Government has certain rights in the invention.

### FIELD OF INVENTION

The present invention generally relates to the deposition of nanowires and other nanoparticles on surfaces.

### BACKGROUND

It is widely recognized that the large-scale placement and orientation of nanostructures from a solution phase with controlled position would have significant impact on the field of nanotechnology. To this end, researchers have explored dielectrophoresis, gas flow, magnetic alignment, electrospray, quasi-two-dimensional nematic phases, electrospinning, and ink-jet printing. However, none of these techniques has yielded a process easily scalable to large areas with good control of placement and orientation.

### SUMMARY OF THE INVENTION

The present invention generally relates to the deposition of nanowires and other nanoparticles on surfaces. The subject matter of the present invention involves, in some cases, interrelated products, alternative solutions to a particular problem, and/or a plurality of different uses of one or more systems and/or articles.

In one aspect, the present invention is directed to an article. According to one set of embodiments, the article comprises a surface comprising a plurality of relatively hydrophilic regions and a plurality of relatively hydrophobic regions. In some cases, at least one of the relatively hydrophilic regions has a minimum surface dimension of no more than about 3000 nm. In certain cases, at least one of the relatively hydrophilic regions contains a plurality of elongate nanoscale objects that are substantially aligned relative to each other.

According to another set of embodiments, the article includes a surface comprising a plurality of relatively hydrophilic regions and a plurality of relatively hydrophobic regions. In some cases, at least one of the relatively hydrophilic regions having a minimum surface dimension of no more than about 3000 nm and containing an aqueous fluid. In one embodiment, the relatively hydrophobic regions are substantially free of the aqueous fluid.

In yet another set of embodiments, the article includes a surface comprising a plurality of relatively hydrophilic regions and a plurality of relatively hydrophobic regions. In one embodiment, the plurality of relatively hydrophobic regions is present on the surface such that a straight line having a length of exactly 4 micrometers can be drawn on the surface that intersects with at least 2 relatively hydrophilic regions.

In another aspect, the present invention is generally directed to a method. In one set of embodiments, the method includes acts of substantially covering at least a portion of a surface with a fluid, the fluid containing nanoscale objects; causing the fluid to form discrete fluidic droplets, at least some of which have a minimum surface dimension of no more than about 3000 nm and are spaced from a nearest neighbor droplet by no more than 3000 nm; and causing evaporation of fluid from the fluidic droplets such that at least some of the nanoscale objects deposit substantially at the center of the respective fluidic droplets.

In another set of embodiments, the method includes acts of substantially covering at least a portion of a surface with a continuous fluid, and causing the fluid to form discrete fluidic droplets. In some cases, at least some of which have a minimum surface dimension of no more than about 3000 nm and are spaced from a nearest neighbor droplet by no more than 3000 nm. In certain instances, the discrete fluidic droplets are separated by a region substantially free of the fluid.

The method, in yet another set of embodiments, includes acts of substantially covering at least a portion of a surface with a continuous fluid, and causing the fluid to form discrete fluidic droplets such that a straight line having a length of exactly 4 micrometers can be drawn on the surface that intersects with at least 2 discrete fluidic droplets.

In another aspect, the present invention is directed to a method of making one or more of the embodiments described herein, for example, a surface containing aligned nanowires. In another aspect, the present invention is directed to a method of using one or more of the embodiments described herein, for example, a surface containing aligned nanowires.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIGS. 1A-1H illustrate centerline positioning of nanotubes in the nanometer and sub-micrometer sized cylindrical droplets, according to certain embodiments of the invention;

FIGS. 2A-2B illustrate multiple depositions of nanotubes on a surface, in accordance with another embodiment of the invention;

FIGS. 3A-3F illustrate control of positioning and alignment of nanotubes on a surface, in yet another embodiment of the invention;

FIGS. 4A-4C show statistical data for the positioning of nanotubes as a function of the size of the droplets containing the nanotubes, in one embodiment of the invention;

FIGS. 5A-5D illustrate cylindrical droplets on a surface, in yet another embodiment of the invention;

FIGS. 6A-6C schematically illustrate evaporative transport within a droplet, in accordance with one embodiment of the invention;

FIGS. 7A-7B illustrate changes in contact angle over time, in another embodiment of the invention; and

FIGS. 8A-8D illustrate nanotube deposition due to fluid flow, in still another embodiment of the invention.

### DETAILED DESCRIPTION

The present invention generally relates to the deposition of nanowires and other nanoparticles on surfaces. According to one aspect of the invention, a fluid containing nanoscale objects, such as nanowires, is deposited on a surface having one or more relatively hydrophilic regions and one or more relatively hydrophobic regions. If the fluid is hydrophilic, it will preferentially be located in the relatively hydrophilic regions (or vice versa if the fluid is relatively hydrophobic). The fluid is then allowed to evaporate to cause the nanoscale objects to deposit. For instance, the rate of evaporation may be controlled so as to allow the nanoscale objects to substantially deposit at the centers of the regions and/or at a rate that causes the nanoscale objects to become substantially aligned. In some cases, the regions may be relatively small, e.g., having a minimum surface dimension of less than about 3000 nm. In one set of embodiments, one or more cylindrical droplets may be formed on the surface. For example, the surface may contain a relatively hydrophilic region, having a large surface aspect ratio, surrounded by a relatively hydrophobic region, such that an aqueous fluid deposited on the relatively hydrophilic region forms a cylindrical droplet. Other aspects of the present invention are directed to methods for creating and using such articles, methods for promoting such articles, or the like.

One aspect of the present invention is generally directed to the deposition of nanoscale objects, such as nanowires, on a surface. The surface may be any suitable surface and formed from any suitable material, for instance, a semiconductor such as silicon, germanium, GaAs, InAs, or the like; a metal surface such as iron, copper, gold, silver, or the like; a polymer; etc. In some cases, the surface comprises gold, e.g., as a coating covering at least part of the surface. The gold coating may have any suitable thickness and may be used, for instance, in embodiments where a self-assembled monolayer is attached to the surface, as discussed below.

As used herein, a “nanoscale object” is an object having a smallest cross-sectional width or dimension of less than about 1 micrometer, and in some embodiments, less than about 750 nm, less than about 500 nm, less than about 200 nm, less than about 150 nm, less than about 100 nm, less than about 70, less than about 50 nm, less than about 20 nm, less than about 10 nm, or less than about 5 nm. In other embodiments, the cross-sectional dimension can be less than 2 nm or 1 nm. As used herein, a “width” of an article is the distance of a straight line from a point on a perimeter of the article, through the center of the article, to another point on the perimeter of the article. The nanoscale object may be spherical or non-spherical, and the nanoscale object may be solid or hollow. Any nanoscale objects can be used in any of the embodiments described herein, including, but not limited to, nanoparticles, carbon nanotubes, molecular wires (i.e., wires formed of a single molecule), nanorods, nanowires, nanowhiskers, inorganic nanoparticles, and the like. A wide variety of these and other nanoscale objects can be applied to surfaces, as discussed in detail, in patterns that are useful for electronic devices. The nanoscale objects may be made out of any suitable material. In some cases, more than one nanoscale object may be present, and the nanoscale objects may be of the same or of different compositions.

The nanoscale object may be elongate in some cases, e.g., having an aspect ratio (longest dimension to shortest dimension of the nanoscale object) of greater than about 2:1. For instance, the nanoscale object may have an aspect ratio of greater than about 3:1, greater than about 4:1, greater than about 5:1, greater than about 10:1, greater than about 25:1, greater than about 50:1, greater than about 75:1, greater than about 100:1, greater than about 150:1, greater than about 250:1, greater than about 500:1, greater than about 750:1, or greater than about 1000:1 or more in some cases.

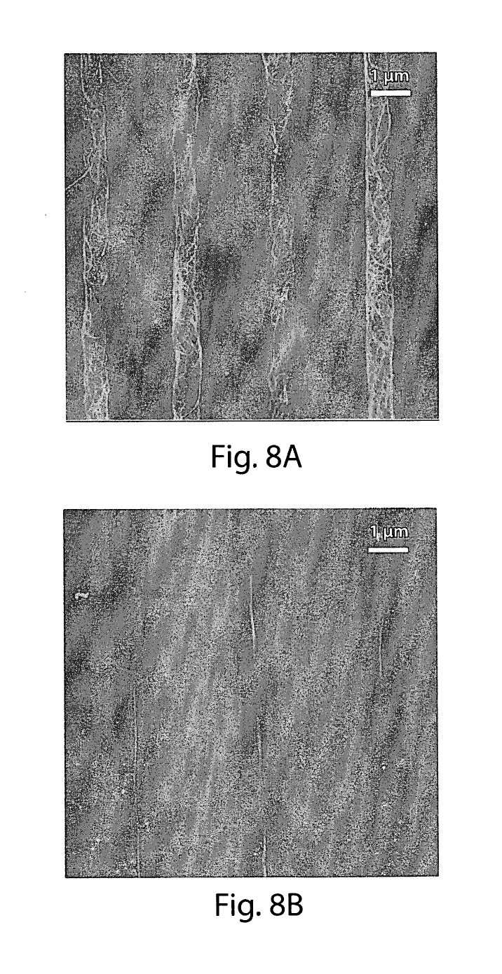

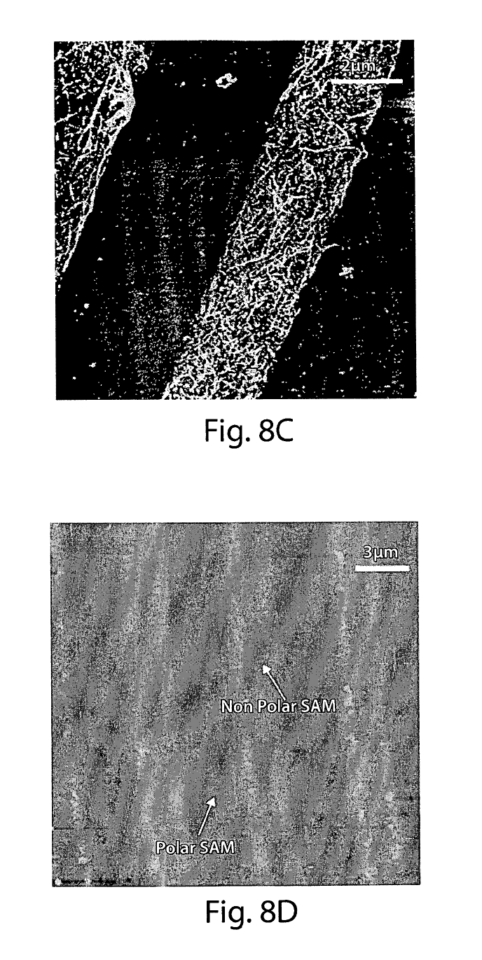

In some cases, as discussed below, the elongate nanoscale objects may be deposited on a surface such that they are substantially aligned relative to each other. As used herein, elongate nanoscale objects that are “substantially aligned relative to each other” are positioned such that at least about 70%, at least about 80%, or at least about 90% of the elongate nanoscale objects that are within about 20°, about 10°, or about 5° of each other, where the longitudinal axis is defined by the direction of the maximum possible spatial dimension present within the nanoscale object. Determination of alignment can be performed by any suitable technique, for example, microscopy, such as SEM (scanning electron microscopy) or AFM (atomic force microscopy). Non-limiting examples of AFM images of surfaces containing nanoscale objects are shown in FIG. 8.

The nanoscale objects may be contained within a fluid that is deposited on a surface, where the fluid is allowed to evaporate, allowing the nanoscale objects to become deposited on the surface. In some cases, as discussed below, evaporation of the fluid may cause the nanoscale objects to become aligned and/or to move to the center of the fluid. The fluid may be aqueous (being substantially miscible in pure water) or organic (being substantially immiscible in pure water).

In some cases, the fluid comprises water (optionally containing other substances, such as salts or surfactants). However, in other cases, the fluid may comprise other liquids, and/or other materials. As used herein, the term “fluid” generally refers to a substance that tends to flow and to conform to the outline of its container. Typically, fluids are materials that are unable to withstand a static shear stress, and when a shear stress is applied, the fluid experiences a continuing and permanent distortion. The fluid may have any suitable viscosity that permits at least some flow of the fluid. Non-limiting examples of fluids include liquids, viscoelastic fluids, or the like.

In some instances, the surface may be patterned with one or more regions that are hydrophobic and/or hydrophilic, and/or relatively hydrophobic and/or relatively hydrophilic. For instance, the surface may contain one or more relatively hydrophilic regions and one or more relatively hydrophobic regions (i.e., relative to each other). In some cases, a hydrophilic region is one that has a contact angle with water and air under ambient conditions (25° C. and 1 atm) of less than about 50°, and a hydrophobic region is one that has a contact angle with water and air under ambient conditions of greater than about 50°. Relative hydrophobicity/hydrophilicity can be determined, for instance, through a comparison of their relative contact angles with water. A fluid (e.g., one containing nanoscale objects such as nanotubes) may be disposed on the surface such that the fluid preferentially fills the hydrophilic and/or the hydrophobic regions. In some cases, the fluid may become “pinned” in the region, e.g., such that the fluid continues to fill the region as fluid is removed (such as through evaporation).

According to one set of embodiments, the surface may be patterned with a self-assembled monolayer, which may be used to control the hydrophilicity/hydrophobicity of portions of the surface (e.g., rendering them hydrophilic, hydrophobic, etc.). For instance, cystamine may be deposited on a surface as a self-assembled monolayer to increase hydrophilicity, octadecanethiol may be deposited on a surface as a self-assembled monolayer to increase hydrophobicity, or the like. Additional examples of moieties that are hydrophilic include, but are not limited to, chemicals terminated with polar chemical groups (such as amino or carboxyl moieties); additional examples of moieties that are hydrophobic include, but are not limited to, chemicals terminated with non-polar groups (such as methyl moieties). Non-limiting examples of systems and methods for producing such surfaces and depositing a self-assembled monolayer on the surface (e.g., a surface comprising gold) are disclosed in Kumar, et al., “Formation of Microstamped Patterns on Surfaces and Derivative Articles,” U.S. Pat. No. 5,512,131, issued on Apr. 30, 1996, incorporated herein by reference. Other systems and methods for microcontact printing of a surface will be known to those of ordinary skill in the art.

In some cases, the surface may printed such that at least one of the regions (e.g., a hydrophilic region or a hydrophobic region) is elongate, e.g., as discussed above. For instance, the region may have a first surface dimension and a second surface dimension at least about 10 times or at least about 100 times the first surface dimension, or any other aspect ratio, such as those discussed above. The surface dimension is to be taken along the surface, and not in a direction perpendicular to the surface. The region may have any suitable shape, e.g., an elongated line, a rectangle, a circle, an oval, an irregular shape, or the like. As discussed below, such regions may be useful for alignment of nanoscale objects, according to some embodiments.

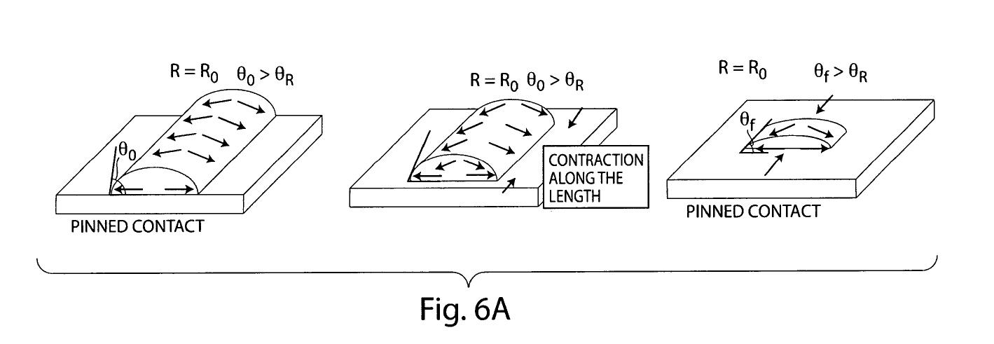

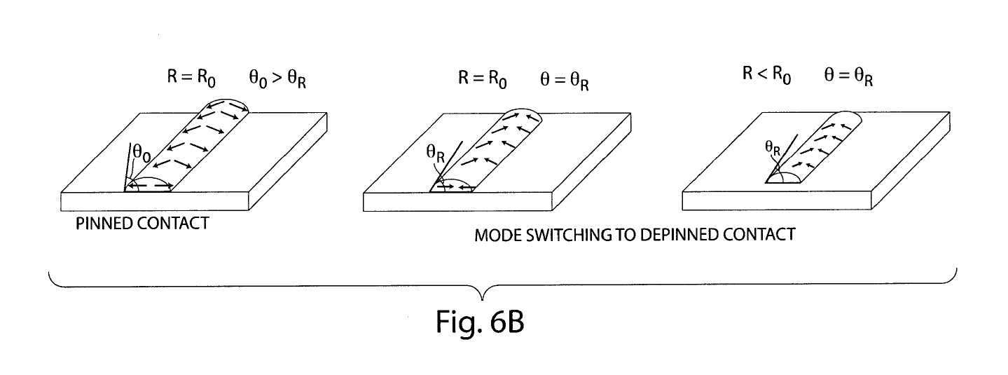

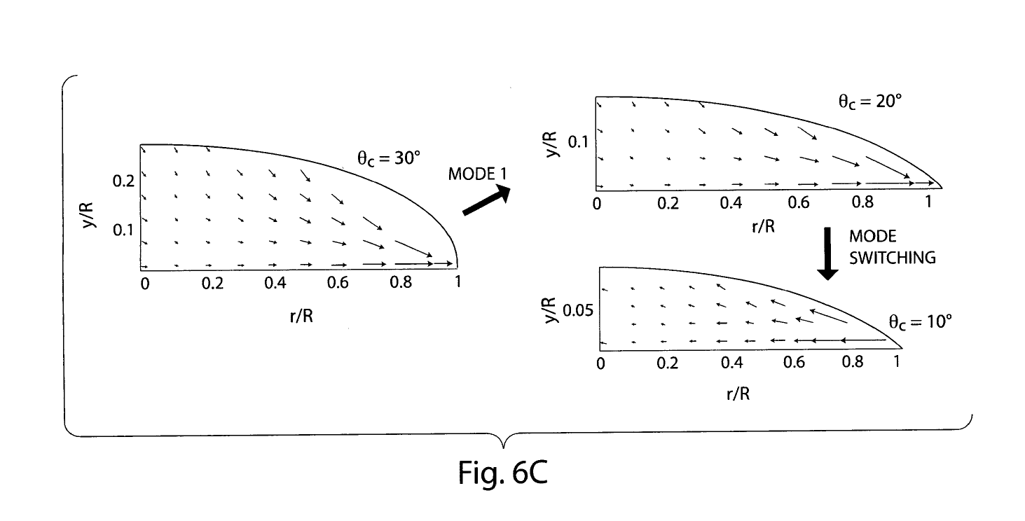

In some cases, an elongate region may be useful for creating a fluidic droplet having a substantially cylindrical shape on the surface, e.g., as is illustrated schematically in FIG. 6. The maximum height of the liquid or other fluid above the region may be the same, greater than, or less than the width of the region, for example, depending on the volume of liquid present. In some cases, the relative hydrophilicity/hydrophobicity of the regions may be sufficient to ensure that regions that are relatively hydrophobic (or relatively hydrophilic) are generally free of the fluid containing the nanoscale objects.

In one embodiment, a plurality of such regions are present on a surface, and in some cases, the plurality of regions may be aligned substantially parallel to each other, e.g., the regions are positioned such that at least about 70%, at least about 80%, or at least about 90% of the regions define longitudinal axes that are within about 20°, about 10°, or about 5° of each other, where the longitudinal axis of each region is defined by the direction of the maximum possible surface dimension within that region.

In some cases, one or more regions may have a minimum surface dimension of less than about 3000 nm, i.e., such that the region has a width of less than this dimension. In other cases, the region may have a minimum surface dimension of less than about 1000 nm, less than about 750 nm, less than about 500 nm, less than about 300 nm, less than about 250 nm, less than about 200 nm, etc. Such regions may be positioned relatively close to each other in certain embodiments of the invention, as discussed below. The regions may be positioned on the surface in any pattern, e.g., in a regular or an irregular pattern, as a series of stripes, or the like.

For instance, the regions may be placed on the surface in a relatively high linear density of regions. As a non-limiting example, the regions may be present on the surface such that a straight line having a length of exactly 4 micrometers can be drawn on the surface that intersects with at least 2 regions, at least 3 regions, at least 4 regions, at least 5 regions, etc. In contrast, in many prior art techniques, regions may be formed having minimum surface dimensions that are grater than at least 5 micrometers, at least 10 micrometers, etc., such that it is not possible to draw a straight line on the surface that intersects with at least 2 regions, at least 3 regions, etc. Such densities may allow, for instance, a plurality of nanoscale objects, such as nanowires, to be deposited in specific locations on the surface, without being deposited in other regions.

In some cases, the fluid may be controlled to flow into the hydrophilic and/or the hydrophobic regions by the addition of a suitable surfactant, for example, sodium dodecyl sulfate (SDS). The surfactant may be any material able to change the surface tension of the fluid, and may be present in any suitable concentration, for example, less than about 5 wt % or about 10 wt %. In some cases, more than about 1 wt % of surfactant is present.

In one aspect, a fluid containing nanoscale objects is deposited on a surface, and the fluid may be removed, for instance, through evaporation, and/or other methods, such as by aspiration. Removal of the fluid allows the nanoscale objects to be deposited on the surface, according to certain embodiments. The fluid may be caused to form one or more discrete droplets (e.g., such that the droplets are surrounded by regions substantially free of the fluid), for example, through the use of surfaces having different hydrophilicities and/or hydrophobicities, such as described above. For example, a fluid may be placed on a surface, substantially covering at least a portion of the surface, and allowed to evaporate or to otherwise fill a relatively hydrophilic or a relatively hydrophobic portion of the surface. Thus, for example, the fluid may be caused to form circular droplets on the surface (e.g., if the regions have the shape of circles), or cylindrical droplets (e.g., if the regions are present as stripes).

By controlling the size and/or the rate at which the fluid leaves the surface, e.g., via evaporation, the placement of the nanoscale objects may be controlled. The rate of evaporation may be controlled, for instance, by controlling the atmosphere in which the evaporation occurs. For example, if the fluid comprises water, the rate of evaporation of water from the surface can be controlled by controlling the relative humidity. The same techniques can be used with other volatile fluids; by controlling the amount of the fluid present within the atmosphere surrounding the surface, the rate at which the fluid volatizes from the surface can be controlled. In some embodiments, the relative humidity may be controlled using any suitable techniques known to those of ordinary skill in the art. The relative humidity (or the equivalent for other fluids) may be controlled to any suitable level, depending on the application. For instance, the relative humidity may be controlled to be greater than about 25%, greater than about 50%, greater than about 75%, etc., and/or less than about 25%, less than about 50%, less than about 75%, etc., depending on the rate of evaporation that is desired. For instance, and without wishing to be bound by any theory, it is believed that high relative humidities would cause a slower rate of evaporation of a sample (e.g., a sample containing aqueous components), relative to lower relative humidities.

It has been found that, under some evaporation conditions, nanoscale objects present within a fluid that is undergoing evaporation have sufficient time to move from a first location within the fluid to a second location within the fluid as the fluid evaporates. Thus, nanoscale objects may be drawn towards the center of a droplet, or towards the edges of the droplet, depending on the evaporation conditions. For instance, as is shown in FIG. 6A, if the evaporation occurs with pinned contact (i.e., where the area of the droplet on the surface remains substantially constant), then nanoscale objects within the fluid will be transported towards the edges of the droplet, and will be deposited there. Conversely, if the evaporation occurs with depinned contact (i.e., where the area of the droplet on the surface changes as the droplet evaporates), then nanoscale objects within the fluid will be drawn towards the center of the droplet, and will be deposited there. In some cases, substantial alignment of the nanoscale objects (if the nanoscale objects are elongate) may occur as part of the evaporation process.

Under suitable conditions, the flow of fluid towards the centers of the droplets may cause at least some of the nanoscale objects to deposit substantially at the center of the respective fluidic droplets. In some embodiments, e.g., if elongate nanoscale objects are used, the nanoscale objects may become aligned substantially in the center of the droplets (e.g. along a line) as they are transported and deposited substantially at the centerline regions of the droplet. Examples of such droplets, and the evaporation that occurs in such droplets, are shown in FIG. 6.

In certain aspects, after depositing the nanoscale objects on a surface, the nanoscale objects may be connected, e.g., as part of an electrical device. For example, a surface may contain a first electrode and a second electrode not in direct contact with the first electrode, such that the first electrode and second electrode are contacted by one or more deposited nanoscale objects. The electrodes may be on the surface prior to deposition of the nanoscale objects, and/or deposited on the surface after deposition of the nanoscale objects. a specific non-limiting example, one or more carbon nanotubes may be deposited, using techniques such as those described above, to contact and electrically connect the first and the second electrode. The electrodes may be formed from any suitable materials, and may the same or different. For example, the electrodes may be gold, silver, copper, nickel, or the like, and may be deposited on the surface using any suitable technique, for example CVD techniques.

U.S. Provisional Patent Application Ser. No. 61/107,302, filed Oct. 21, 2008, entitled “Deposition of Nanowires and Other Nanoscale Objects on Surfaces,” by Strand, et al., is incorporated herein by reference.

The following examples are intended to illustrate certain embodiments of the present invention, but do not exemplify the full scope of the invention.

### Example 1

This example illustrates the creation of high aspect ratio, cylindrical droplets of nanometer diameter (˜175 nm) using a parallel pattern of alternating hydrophobic and hydrophilic SAM layers. These SAM layers were created by microcontacting printing techniques and cylindrical droplets were selectively formed on polar SAM regions. The diameter of these droplets were generally the same as the width of the polar SAM regions, and were controllable. It was found that as the diameter of the droplet was reduced below 1 micrometer under these conditions, a reversal of the internal flow within the droplet was evident during evaporation, which allowed accurate alignment and placement of nanotubes along the droplet centerline, with approximately 95% precision. The transition from edge deposition of the nanotubes for droplets greater than about 3 micrometers in width to centerline deposition of the nanotubes for droplets less than about 950 nm in width involved an intermediate region with relatively little coherent orientation or placement control. In addition, Example 2, below, illustrates a model that describes the transition from radially outward to inward flow. This technique can be used for precisely aligning and placing anisotropic nanotubes or nanoparticles with arbitrary surface chemistries.

The platform to create the cylindrical droplets used in this example was a patterned gold surface with alternating rectangular stripes of polar and non polar SAMs. The formation of droplets occurred when a homogenous film of 1 wt % sodium dodecyl sulfate (SDS) SWNT (single-walled nanotube) solution deposited on the patterned area segregated into the desired cylindrical droplets on the polar SAM region. For creation of micrometer-sized (2R≧3 micrometers) droplets, the solution could be deposited by either immersion of the substrate into it or by application of a few drops to cover the surface forming a homogenous film. In some cases, to create nanometer-sized cylindrical droplets (e.g., 175 nm to 950 nm width), a thin film of SWNT solution was used on the patterned area to ensure its facile rupturing into nanometer-sized droplets. For this purpose, it was easiest to utilize the foam from an SDS-SWNT solution to create the desired thin film.

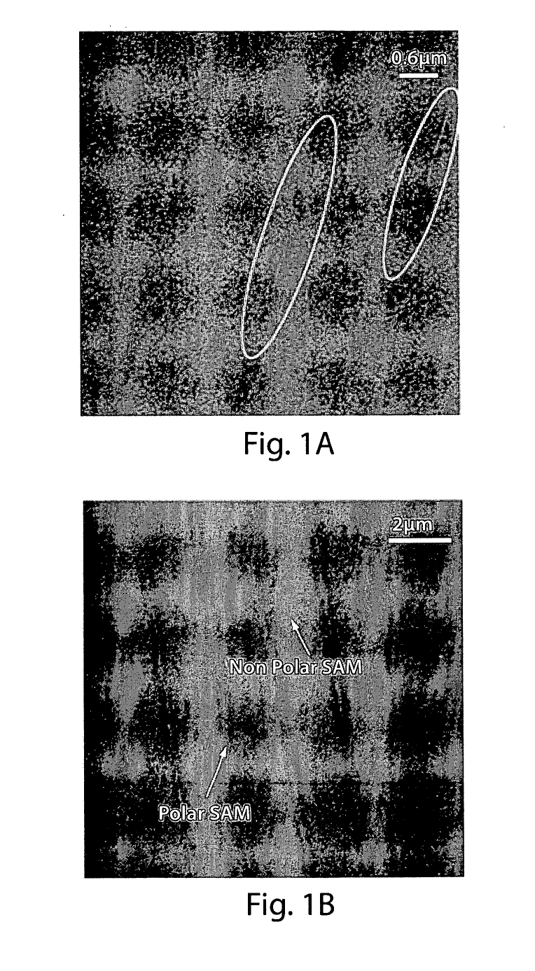

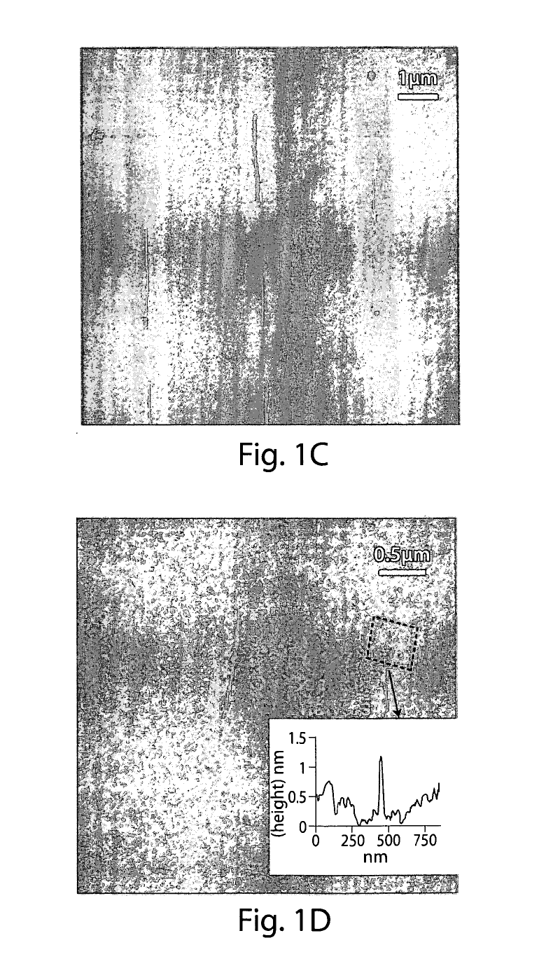

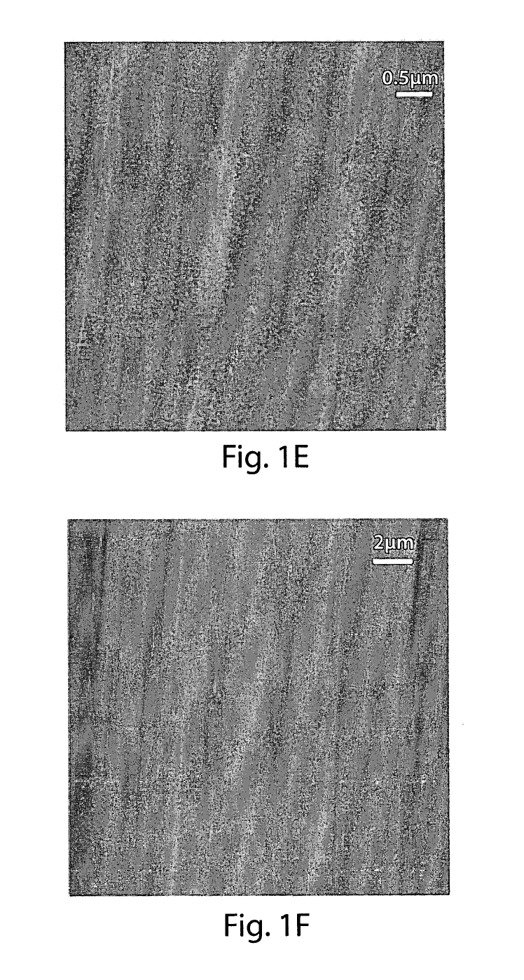

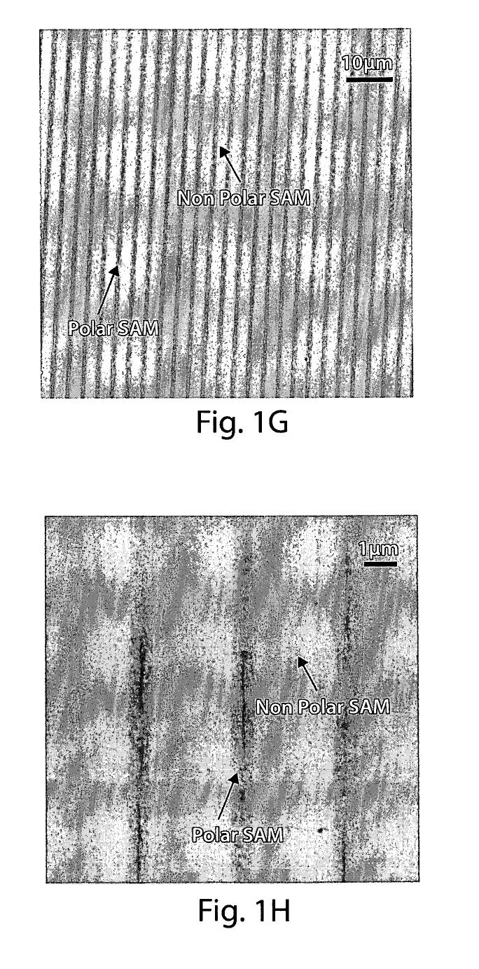

It was found that when the width of the polar stripes (i.e., the diameter of the cylindrical droplets) in the patterned area was reduced to below about 1 micrometer, the resulting AFM (atomic force microscopy) images showed centerline placement and substantial alignment of the nanotubes. This centerline positioning of nanotubes in the nanometer and sub-micrometer sized cylindrical droplets is indicated in the AFM topographic images in FIG. 1. This included cylindrical droplets with 2R˜175, 425 and 950 nm (FIGS. 1A, 1B, and 1C, respectively). FIGS. 1D and 1E are high magnification images, showing substantially parallel alignment and centerline positioning of the nanotubes with moderate and high coverage, respectively, for a 350 nm wide polar SAM. FIG. 1D is a section analysis showing the height of a single nanotube. The inset in FIG. 1D is a section analysis of the area in the dotted region of FIG. 1D, demonstrating deposition of individual SWNTs (height ˜1.3 nm). Further examples are shown in FIGS. 1G and 1H, with FIG. 1G being at low magnification and showing alternating polar (˜1 micrometer) and non-polar (˜2.5 micrometer) regions, and FIG. 1H being at a higher magnification.

The accuracy of this centerline deposition was more than 95% (i.e., more than 95% of the nanotubes deposited within ±5% of r/R=0). Shorter nanotubes, aligned on 450 nm wide polar SAM, as shown in FIG. 1F (length ˜200-600 nm), also showed similar results. Thus, centerline positioning may be independent of nanotube length. Additionally, no SWNTs were deposited when the patterned substrate was immersed into the SWNTs solution for 30 minutes with no subsequent drying (i.e. no droplet formation), which suggested that nanotube deposition was caused by the formation and evaporation of the cylindrical droplets, rather than any interaction between the polar SAM and the SWNTs.

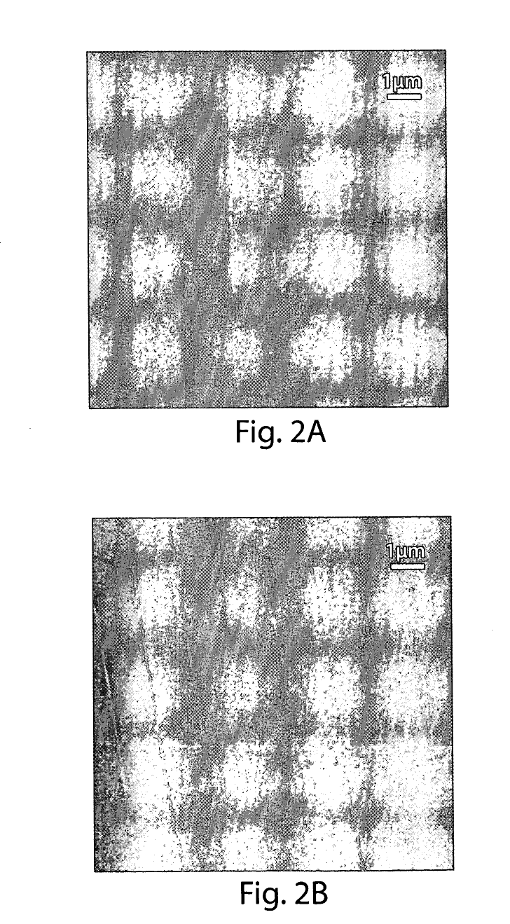

Another useful aspect of this technique is the level of control for nanotube coverage. Control could be tuned by cycling the deposition procedure a number of times. The total linear coverage, in some cases, was approximately proportional to the number of times the SWNT solution was deposited (or the droplets are created and evaporated). For instance, single deposition yielded sparse coverage (FIG. 2A). However, multiple depositions increased the amount of coverage (FIG. 2B), until the deposition was nearly uniform. In FIG. 2B, the SWNT solution was deposited on the solution 6 times on the patterned surface, with the solution concentration at ˜5 mg/l. Interestingly, multiple deposition did not result in any positioning error of the nanotubes (i.e., no non-centerline deposition was observed).

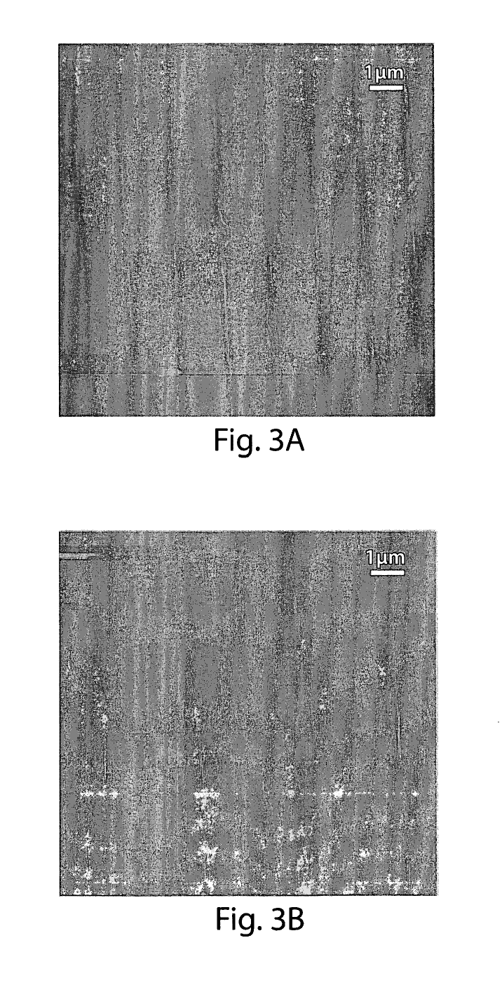

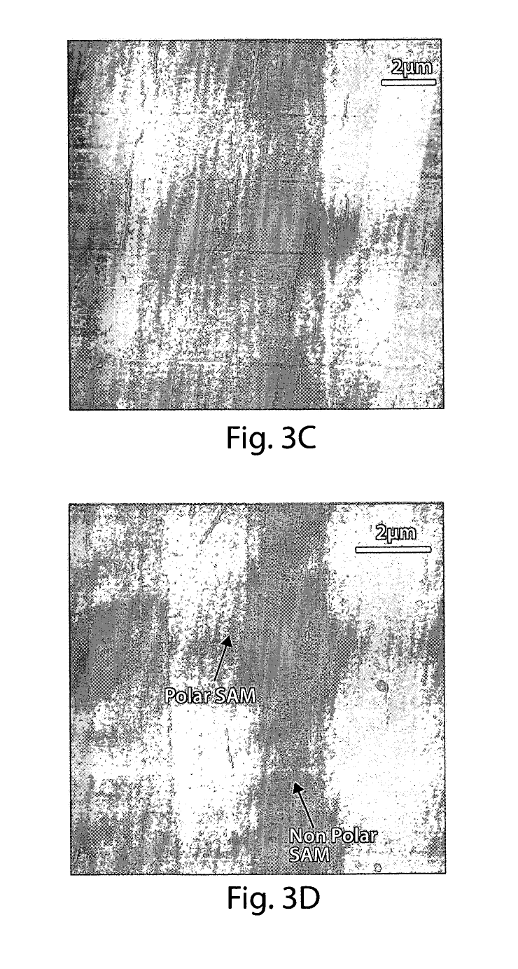

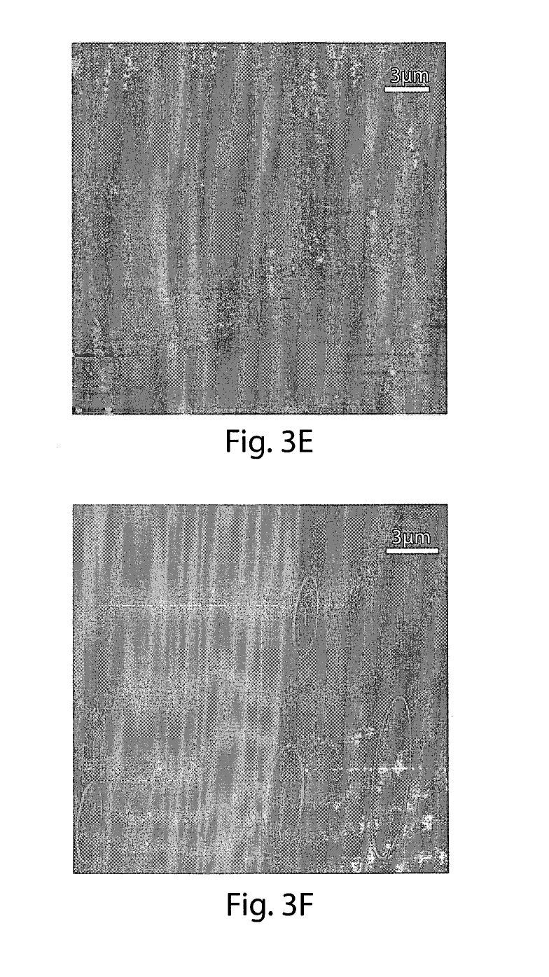

This centerline deposition behavior transitioned to a disordered regime above about 950 nm (2R) under these conditions, which further transitioned to an edge deposition regime above about 3 micrometers (2R). These results are shown in FIG. 3. In this figure, centerline deposition, r/R=0 for nanometer and sub-micrometer sized droplets (2R=175-950 nm) is represented in FIGS. 3A and 3B (2R˜300 nm or ˜950 nm, respectively). In these figures, the nanotubes deposited substantially on the centerline of the droplet, with substantial alignment, with parallel alignment to the edges. In contrast, for edge deposition, r/R=1 for micrometer-sized droplets (2R>3 micrometers) is represented in FIGS. 3E and 3F (2R˜3.1 micrometers or 5.5 micrometers, respectively), with substantial alignment on the edges parallel to the droplet edges. Both of these regimes exhibited substantial alignment of the nanotubes with very little apparent error. A transition to a disordered regime (FIGS. 3C and 3D, 2R˜2 micrometers) was observed between these two regimes. In this transitional regime, the SWNTs deposited at some intermediate value of r/R (i.e., 0<r/R<1) that was not fixed. Additionally, they did not appear to consistently align, and appeared to be deposited with bends along their lengths in some cases.

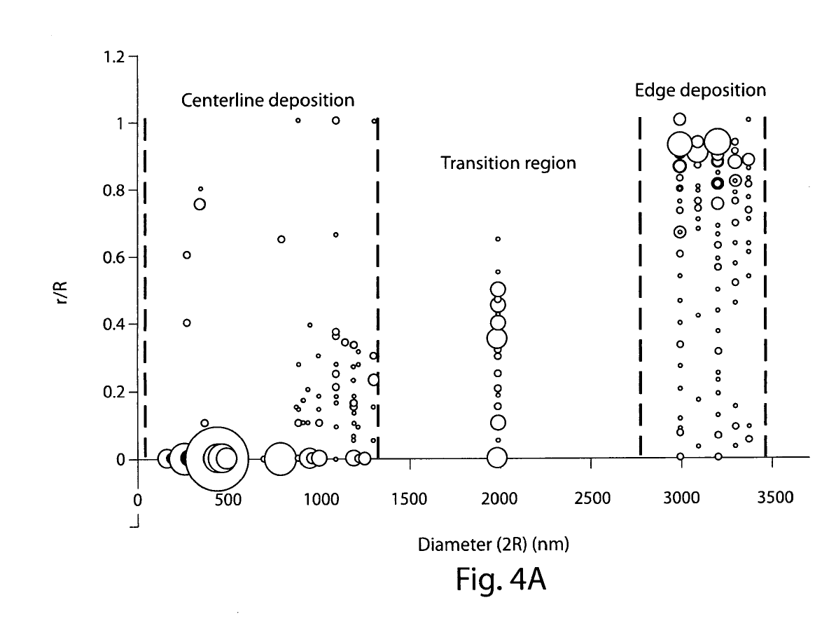

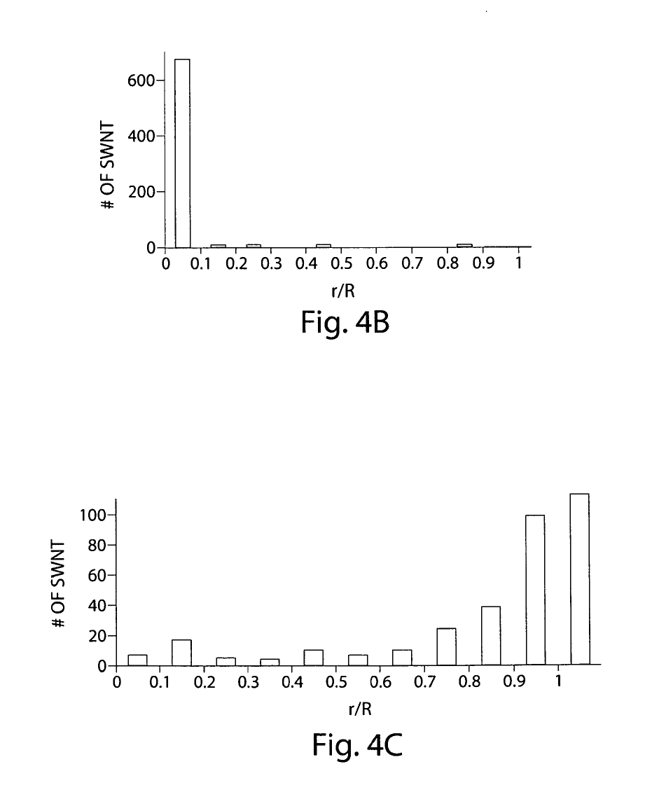

In some experiments, the nanotubes were deposited with notable bends along their length. FIG. 4 shows the three regimes of SWNT positioning. Experimental data was compiled for 1160 nanotubes from 70 AFM images in form of a bubble chart (FIG. 4A) where the size of each bubble is proportional to the number of overlapping data points. (Note that the large bubble area does not imply variation of placement location; it represents the number of overlapping counts observed at precisely the center of the bubble at the specified r/R.) For widths less than about 1 micrometer, about 95% of the nanotubes deposited within ±5% of r/R=0 (at the centerline of the polar SAM region), as is shown in FIG. 4B as a histogram. FIGS. 4B and 4C are histograms for the centerline and edge deposition respectively, showing the accuracy of positioning in these regimes. For polar SAM regions ≧3 micrometers, most of the nanotubes deposited at the edges of the region, as is shown in FIG. 4C.

A further example is shown in FIG. 8, which is a comparison of the SWNT deposition guided by direct interaction between the nanotubes and the SAM and by internal fluid flow. FIGS. 8A and 8C illustrate nanotubes suspended in organic solvent (orthodichlorobenzene, ODBC) deposited on SAM. Deposition occurred as networks in the polar SAM regions. FIGS. 8B and 8D illustrate nanotubes suspended in 1 wt % SDS in water. Parallel alignment and positioning were controlled by the width of the polar SAM.

### Example 2

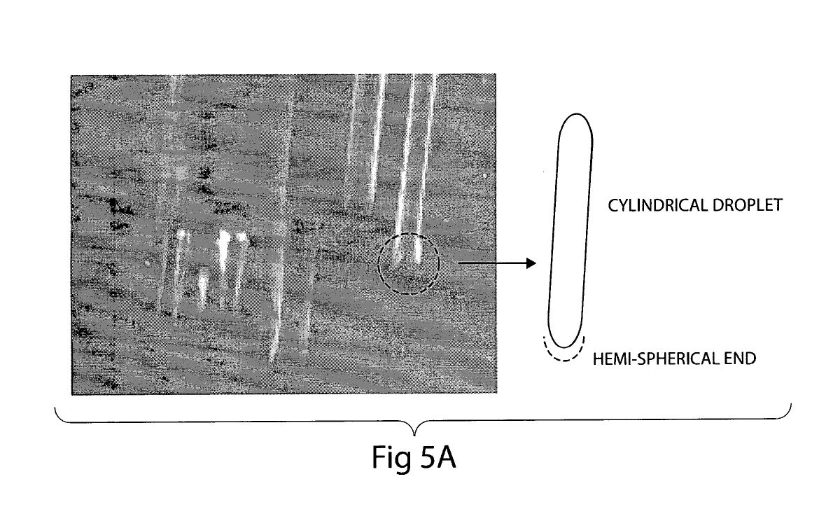

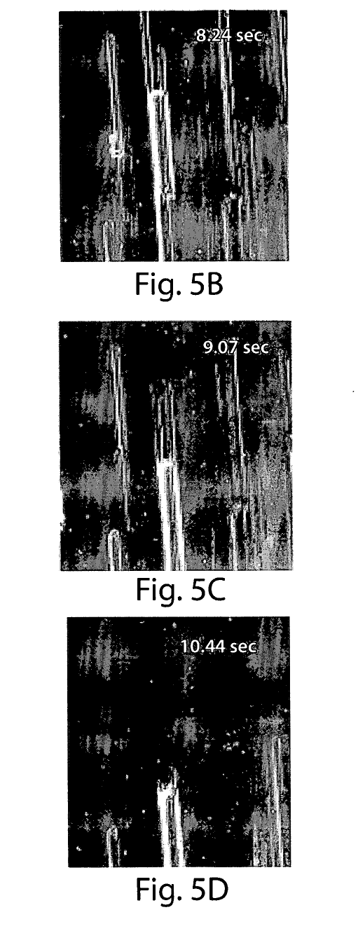

This example illustrates a model for the mechanism of cylindrical droplet evaporation to show the role of droplet size in positioning of the trapped nanotubes discussed in Example 1. For this, real-time video microscopy of the experiments Example 1 was analyzed for the formation and evaporation of micrometer-sized cylindrical droplets (2R˜3.5 micrometers). It is observed that their evaporative mode was pinned contact area (i.e. 2R remained constant), that evaporation terminated as the ends along the length of the cylindrical droplet contract rapidly, and that the final contact angle did not decrease to zero (or even to the receding contact angle (θᵣ), as the contact along the width remained pinned throughout). A schematic of the mechanism under these conditions is presented in FIG. 6A. Fast contraction (FIG. 5B-5D) along the length of the droplet may lead to high evaporative flux at these ends. The width (diameter) of each droplet was about 3.5 micrometers. This evaporative flux was equated to the rate at which the contraction occurs (or the velocities of the moving ends) and was found to be approximately 1000 times higher than the normal evaporative flux.

In FIG. 6A, schematically, micrometer-sized droplets (2R>3 micrometers) start evaporating with a pinned contact area and decreasing contact angle (θ₀→θ_{f}). This drying process establishes an outward radial flow field within the droplet. The evaporation process terminates as the ends along the length of the cylindrical droplets contract rapidly due to rapid drying at the free ends. Termination takes place before the contact angle drops below the receding contact angle (θ_{R},θ_{f}>θ_{R}). This maintains pinned contact along the width (2R=constant) throughout the evaporation. In FIG. 6B, nanometer and sub-micrometer sized (narrow) droplets (2R<1 micrometer) start evaporating with pinned contact along the width. The contact angle rapidly falls down

$$( \frac{d {θ}_{c}}{d t} ∝ \frac{1}{R} )$$

to the receding contact angle θ_{R} (or equivalently, θᵣ), and is maintained constant thereafter. At this point the evaporation mode switches to depinned contact (shrinking) resulting in a radially inward flow field. FIG. 6C shows a velocity vector field representation in the nanometer or sub-micrometer sized droplets. Initial evaporation causes fluid transport to the edges (“mode 1”), which then switches to fluid transport towards the center (“mode 2”) after the contact angle reaches θ_{R}.

The evaporative flux J(r) of an evaporating spherical droplet at r distance from the center has been solved, where:

J(r)∝(R−r)^{-λ} where A=(π−28,)/(2π−2θ_{c}) (1)

Here, R is the radius and θ_{c} is the contact angle of the droplet. For hydrophilic substrates (0<θ_{c}<π/2), A is non-negative and J(r) is very large near the contact line (r->R). The ends along the length of a cylindrical droplet can be approximated to be hemi-spherical (FIG. 5A) and hence, here a comparatively high value of evaporative flux is expected according to Equation (1). This is also supported by calculations of J(r) from video microscopy of droplet evaporation that yield a value Jₛ (flux from the open ends along the length) that is about 1000 times more than normal evaporative flux Jₒ (the flux from the droplet curvilinear surface).

The rate of decrease of the contact angle for cylindrical droplets evaporating with pinned contact has been solved, and is:

$$\frac{d {θ}_{c}}{d t} = - ( \frac{{J}_{o} {θ}_{c}}{p} \frac{1}{R} \frac{{sin}^{2} {θ}_{c}}{( sin {θ}_{c} - {θ}_{c} cos {θ}_{c} )} ) \qquad ( 2 )$$

Here, p is the density of the droplet liquid. This equation suggests that the rate of decrease in contact angle is inversely proportional to the radius of the droplet

$$( \frac{d {θ}_{c}}{d t} ∝ \frac{1}{R} ) .$$

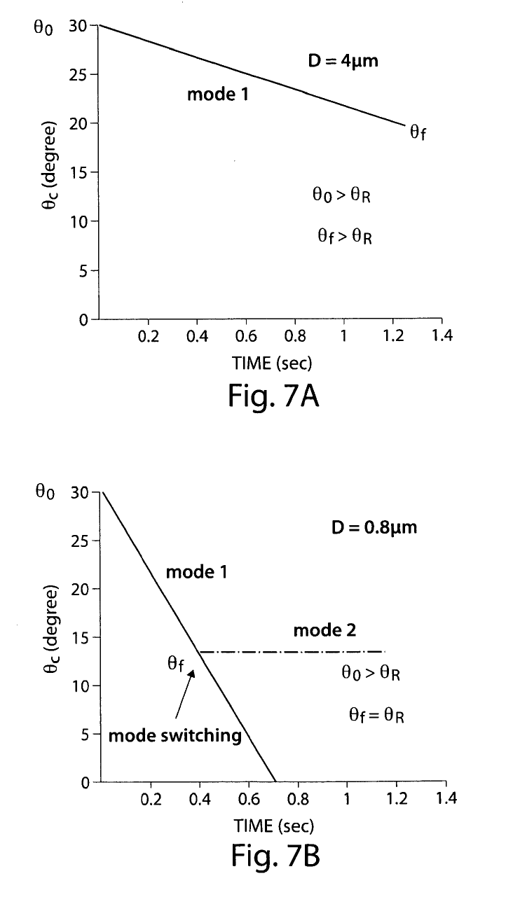

Hence, a faster decrease in contact angle of nanometer and sub-micrometer sized droplets would be expected as compared to micrometer-sized droplets (FIG. 7).

FIG. 7A shows data corresponding a 4 micrometer-diameter droplet, as a representative example. The change in contact angle for micrometer sized (wide) droplets was small and final contact angle did not reach θ_{R}. The only mode of evaporation was pinned contact and contraction along the length lead to termination of evaporation. FIG. 7B shows similar data for a 0.8 micrometer-diameter droplet. The contact angle decreased rapidly for nanometer and sub-micrometer sized (narrow) droplets. The dotted line represents the change in contact angle if the mode of evaporation was pinned contact throughout. Note that the final contact angle went to zero, unlike for the wider droplets in FIG. 7A. However, θ_{R} was greater than zero and hence mode switching takes place at a non-zero contact angle. Evaporative flux for the curvilinear surface (J) was taken from literature values and that for the ends along the length (J_{S}) was calculated by observing the velocity of the contraction.

Accordingly, and without wishing to be bound by any theory, it is believed that the nanometer and sub-micrometer sized droplets start their evaporation with pinned contacts (decreasing contact angle), such as micrometer-sized droplets (FIG. 6B). A rapid fall in the contact angle caused it to quickly attain the receding contact angle value (θ_{R}) and thereafter, the evaporation mode switched to depinned contact (FIG. 7B). This mode switching consequently reverses fluid flow inside the droplet from edge-directed to centerline-directed, where it is able to carry and position SWNTs or other nanoscale objects. However, for larger droplets before the contact angle can reduce to the value of θ_{R}, evaporation along the length causes the droplet to evaporate completely.

To explain the transition region, the contact angle was able to drop to the receding contact angle value, resulting in evaporation mode switching and flow reversal. However, the second mode (i.e., depinned contact) did not survive for sufficient time as contraction along the length causes termination of the drying process. During this short time for survival of the second mode of evaporation, the SWNTs appeared to be unable to reach the centerline, resulting in their deposition at various intermediate positions.

In summary, the hydrodynamic flow patterns inside high aspect ratio evaporating cylindrical droplets can be used for parallel alignment, positioning and/or placement of nanoparticles. These examples illustrate the creation of nanometer diameter cylindrical droplets using alternating hydrophobic and hydrophilic SAM layers made by a micro-contacting printing technique. As the diameter of the droplet was reduced below 1000 nm (e.g., to 950-175 nm), a reversal of the internal flow within the droplets allowed for parallel alignment and placement of carbon nanotubes along the centerline of the droplets with about 95% precision (i.e., such that 95% of the nanotubes deposited within ±5% of r/R=0). The transition from edge deposition for droplets 2R≧3 micrometers to centerline deposition 2R≦950 nm involved a region with no apparent coherent orientation or placement control, which may be evidence of evaporative mode switching. A model was also developed to describe the transition from radially outward to inward flow. The techniques discussed in these examples are thus be useful for aligning and placing individual or bundled anisotropic nanoparticles (i.e. carbon nanotubes) with arbitrary surface chemistries.

The size of the evaporating cylindrical droplet may facilitate control over their mode of evaporation and hence their internal flow pattern, which can be directly utilized to align and position nanoparticles or other nanoscale objects with nanometer precision. Placement may be controlled to be along the centerline for narrow (nanometer and sub-micrometer sized) droplets, but along the edge for wider (micrometer-sized) droplets caused via internal flow patterns that are directed inward and outward respectively. The model for evaporation mode switching successfully explained the transition of placement of SWNT with change in the droplet size. Such a self-assembling system is a promising alternative to conventional manufacturing of devices with nanoscale components.

Methods used in the above experiments include the following. SWNT solutions were prepared as follows. Electric arc synthesized SWNT and HiPco SWNT (batch HPR 107.1) were suspended in 1 wt % sodium dodecyl sulfate (SDS) in DI (deionized) water by 10 min sonication, followed by 2-5 h centrifugation at 30,000 RPM. Different centrifugation time resulted in different concentrations of the SWNT solution.

PDMS stamps were used to pattern the gold surface for formation of cylindrical droplets. Stamps for the nanometer and sub-micrometer sized cylindrical droplets were made from a PMMA (poly(methyl methacrylate)) master. PMMA was hard-baked for ten minutes at 120° C., followed by e-beam lithography writing to make alternating lines and spaces. A 1:15 ratio of crosslinker and monomer was used to keep the PDMS soft and avoid ripping off the PMMA lines during pulling out of the stamp from the master.

Cylindrical droplets were formed as follows. A gold-coated silicon wafer was patterned with alternating rectangular strips of polar (cystamine) and nonpolar (octadecanethiol, ODT) self-assembled monolayer (SAM). The SAMs were made by microcontact printing using a PDMS stamp having alternating lines and spaces features. Cylindrical droplets of SWNT solution in water (1 wt % SDS) formed on the polar rectangular stripes. For 3.5 micrometer-sized droplets, the width of the stripes was ˜3 micrometers (polar SAM) and ˜2.5 micrometers (nonpolar SAMs). For nanometer and sub-micrometer sized cylindrical droplets, the width of the polar SAM was reduced to 175-950 nm with the aid of a PDMS stamp having spaces of sub-micrometer width. E-beam lithography was used to make PMMA masters for fabrication of such PDMS molds with sub-micrometer features. For micrometer-sized droplets, a solution of SWNT (1 wt % SDS in water) was deposited by either immersion of the substrate in it, or by application of a few drops to cover the surface to form a thin, homogeneous film. As the film dried, its height reached a value where the surface free energy was minimized by segregating into the desired cylindrical droplets on the polar SAM regions. For the nanometer and sub-micrometer sized cylindrical droplets, a very thin film (<1 mm) of the SWNT solution was deposited to ensure its rupturing into these extremely small droplets. Foam from the SWNT solution was deposited on the patterned substrate for the formation of the thin film. For sub-micrometer cylindrical droplets formation, both 1 wt % and 5 wt % SDS were used. The results of SWNT deposition did not show any appreciable differences with these different concentrations, but formation of the sub-micrometer sized droplets was easier for 5 wt % SDS than for 1 wt %.

Dimension 3100 (Digital instruments) was used for AFM imaging. SEM imaging was performed with a Zeiss SEM. Gold-coated substrates were prepared by thermally depositing a 5 nm thick Cr layer, followed by a 50 nm Au deposition on a thermally oxidized silicon wafer (600 nm SiO₂, Montco Silicon Technologies) under high vacuum.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. An article, comprising:
a surface comprising a plurality of relatively hydrophilic regions and a plurality of relatively hydrophobic regions, at least one of the relatively hydrophilic regions having a minimum surface dimension of no more than about 3000 nm, wherein at least one of the relatively hydrophilic regions contains a plurality of elongate nanoscale objects that are substantially aligned relative to each other.

2. The article of claim 1, wherein at least one relatively hydrophilic region contains a self-assembled monolayer.

3. The article of claim 1, wherein at least one relatively hydrophilic region contains cystamine.

4. The article of claim 1, wherein at least one relatively hydrophobic region contains a self-assembled monolayer.

5. The article of claim 1, wherein at least one relatively hydrophobic region contains octadecanethiol.

6. The article of claim 1, wherein the plurality of relatively hydrophilic regions and the plurality of relatively hydrophobic regions are created on the surface using microcontact printing.

7. The article of claim 1, wherein at least one of the relatively hydrophilic regions has a first surface dimension and a second surface dimension at least about 10 times the first surface dimension.

8. The article of claim 7, wherein the second surface dimension is at least about 100 times the first surface dimension.

9. The article of claim 7, wherein the surface comprises a plurality of relatively hydrophilic regions having a first surface dimension and a second surface dimension at least about 10 times the first surface dimension, the plurality of relatively hydrophilic regions being substantially parallel to each other.

10. The article of claim 1, wherein at least one relatively hydrophilic regions contains a liquid disposed thereon, the liquid having a substantially cylindrical shape.

11. The article of claim 1, wherein at least one relatively hydrophilic region defines a longitudinal axis, wherein the elongate nanoscale objects are substantially aligned in parallel to the longitudinal axis.

12. The article of claim 1, wherein at least some of the elongate nanoscale objects are nanowires.

13. The article of claim 1, wherein at least some of the elongate nanoscale objects are nanotubes.

14. (canceled)

15. The article of claim 1, wherein at least one of the relatively hydrophilic regions has a minimum surface dimension of no more than about 1000 nm.

16-19. (canceled)

20. The article of claim 1, wherein the surface comprises gold.

21. (canceled)

22. The article of claim 1, wherein the surface comprises a semiconductor.

23. (canceled)

24. The article of claim 1, wherein at least in a part of the surface consists essentially of a semiconductor.

25. The article of claim 1, wherein the surface contains a first electrode and a second electrode not in direct contact with the first electrode, each of the first electrode and the second electrode being positioned in contact with at least one of the elongate nanoscale objects.

26. An article, comprising:
a surface comprising a plurality of relatively hydrophilic regions and a plurality of relatively hydrophobic regions, at least one of the relatively hydrophilic regions having a minimum surface dimension of no more than about 3000 nm and containing an aqueous fluid, wherein the relatively hydrophobic regions are substantially free of the aqueous fluid.

27-31. (canceled)

32. An article, comprising:
a surface comprising a plurality of relatively hydrophilic regions and a plurality of relatively hydrophobic regions, the plurality of relatively hydrophobic regions being present on the surface such that a straight line having a length of exactly 4 micrometers can be drawn on the surface that intersects with at least 2 relatively hydrophilic regions.

33-61. (canceled)
